(19) United States
(12) Patent Application Publication
(10) Pub. No.: US 2013/0009637 A1
(43) Pub. Date: Jan. 10, 2013

(54) MAGNETORESISTANCE ELEMENT AND MAGNETIC SENSOR USING THE SAME

(75) Inventor: Zhang ZHENHONG, Yamanashi (JP)

(73) Assignee: NEC Yamanashi, Ltd., Yamanashi (JP)

(21) Appl. No.: 13/531,937

(22) Filed: Jun. 25, 2012

(30) Foreign Application Priority Data
Jul. 4, 2011 (JP) 2011-148236

(51) Int. Cl. G01R 33/09; B32B 3/10

(52) U.S. Cl. 324/252; 428/195.1

(57) ABSTRACT

To decrease the power consumption of an MR element. The MR element includes a substrate and a magnetoresistance film provided on the substrate. The MR film is in a shape in which a straight line bent in a zigzag form is further bent in a multiple zigzag form. The straight line forms a plurality of configuration parts. Each of the configuration parts is in a form in which a plurality of rectangles in parallel to each other are connected in series in a zigzag form, and the configuration parts are connected to each other in series in a zigzag form.

### CROSS-REFERENCE TO RELATED APPLICATION

This application is based upon and claims the benefit of priority from Japanese patent application No. 2011-148236, filed on Jul. 4, 2011, the disclosure of which is incorporated herein in its entirety by reference.

### BACKGROUND OF THE INVENTION

1. Field of the Invention

The present invention relates to an MR element utilizing magnetoresistance (referred to as MR hereinafter) with which the electric resistance changes by an external magnetic field and to a magnetic sensor using the same.

2. Description of the Related Art

An MR element is a kind of magenetoelectric conversion element, which is an element that detects the magnetic field and converts it to an electric signal. The MR element is constituted with an alloy thin film containing a ferromagnetic metal such as nickel (Ni) or iron (Fe) formed on a substrate. Four resistors are formed by the alloy thin film, and a Wheatstone bridge circuit is constituted by using those resistors. In this case, the resistance values of two resistors out of the four resistors become smaller than the resistance values of the other resistors due to an increase in the intensity of the external magnetic field. Thereby, there is an intermediate potential difference generated in the bridge circuit.

The pattern of the MR element is constituted with a combination of rectangular thin films. The length of the long side of the rectangle is defined as the element length, and the length of the short side is defined as the element width. In this case, when a magnetic field is applied in the perpendicular direction of the element length, the resistance value of the MR element becomes smaller. Thus, the electric current flown in the MR element becomes greater. The resistance value of the MR element is determined by the shape of the rectangle and the thickness of the thin film. The longer the element length is, the greater the resistance value becomes.

The MR element reacts to both the magnetic field of the N→S direction and the magnetic field of the S→N direction. The aspect ratio (the ratio of the element length and the element width of the rectangle) of the pattern of the MR element influences the property of the MR element.

A magnetic sensor is constituted with an MR element and an electronic circuit. The MR element outputs a signal acquired by detecting the external magnetic field, and the electronic circuit processes the signal by performing amplification or the like and outputs it.

Japanese Unexamined Patent Publication 2007-078700 (FIG. 5A) (Patent Document 1) discloses an MR element constituted with a semiconductor thin film. Japanese Unexamined Patent Publication 2009-085645 (FIG. 1) (Patent Document 2) and Japanese Unexamined Patent Publication 2009-250931 (FIG. 1) (Patent Document 3) disclose an MR element in which two MR films formed in a zigzag form are connected in series. Japanese Unexamined Patent Publication Hei 03-264875 (FIG. 1) (Patent Document 4) and Japanese Unexamined Patent Publication Hei 08-130338 (FIG. 2) (Patent Document 5) disclose an MR element in which four MR films formed in a zigzag form are bridge-connected.

Recently, due to reduction in the size of the magnetic sensors, the area of the substrate for forming the MR element has become smaller. Thus, because the resistance value of the MR element becomes smaller, the power consumption of the MR element becomes greater inversely. How to reduce the power consumption is the first issue.

Regarding “UP” (change from a low-level magnetic field to a high-level magnetic field) and “DOWN” (change from a high-level magnetic field to a low-level magnetic field) of an applied magnetic field, there is a hysteresis (a magnetic field intensity difference between “ON” and “OFF” states of a magnetic sensor) in a magnetic sensor, respectively. How to reduce the hysteresis is the second issue.

The magnetic sensor reacts to both the magnetic field of the N→S direction and the magnetic field of the S→N direction. However, there is a magnetic field sensitivity difference between the N→S direction and the S→N direction. How to reduce the magnetic field sensitivity difference is the third issue.

### SUMMARY OF THE INVENTION

The magnetoresistance element according to an exemplary aspect of the invention includes a substrate and a magnetoresistance film provided on the substrate, wherein the magnetoresistance film is in a shape in which a straight line bent in a zigzag form is further bent in a multiple zigzag form.

The magnetic sensor according to another exemplary aspect of the invention includes: the magnetoresistance element according to the present invention; and an electronic circuit which processes a signal of a magnetic field intensity detected by the magnetoresistance element.

### BRIEF DESCRIPTION OF THE DRAWINGS

FIGS. 1A and 1B show plan views of an MR element of a first exemplary embodiment according to the present invention, in which FIG. 1A shows the whole part and FIG. 1B shows a fragmentary enlarged view;

FIG. 2 is a plan view showing an MR element of a second exemplary embodiment according to the present invention;

FIG. 3 is a circuit diagram showing a magnetic sensor of a third exemplary embodiment according to the present invention;

FIG. 4 is a detailed perspective view showing the stereoscopic structure of the magnetic sensor of the third exemplary embodiment;

FIG. 5 is a plan view showing an MR element of a comparative example;

FIG. 6 is a graph 1 showing a magnetic field applied to the MR elements of the comparative example and the second exemplary embodiment;

FIG. 7 is a graph 2 showing a magnetic field applied to the MR elements of the comparative example and the second exemplary embodiment;

FIG. 8 is a graph 1 showing the relation between the applied magnetic field and the output voltage regarding the MR element of the comparative example;

FIG. 9 is a graph 2 showing the relation between the applied magnetic field and the output voltage regarding the MR element of the comparative example;

FIG. 10 is a graph 1 showing the relation between the applied magnetic field and the output voltage regarding the MR element of the second exemplary embodiment; and

FIG. 11 is a graph 2 showing the relation between the applied magnetic field and the output voltage regarding the MR element of the second exemplary embodiment.

### DETAILED DESCRIPTION OF THE PREFERRED EMBODIMENTS

Hereinafter, modes (referred to as “exemplary embodiments” hereinafter) for embodying the present invention will be described by referring to the accompanying drawings. In this Specification and drawings, same reference numerals are used for the same or similar structural elements. The dimensions and ratios of those drawn in the drawings are changed to the values different from the actual values for making it easy to be comprehended and to be illustrated.

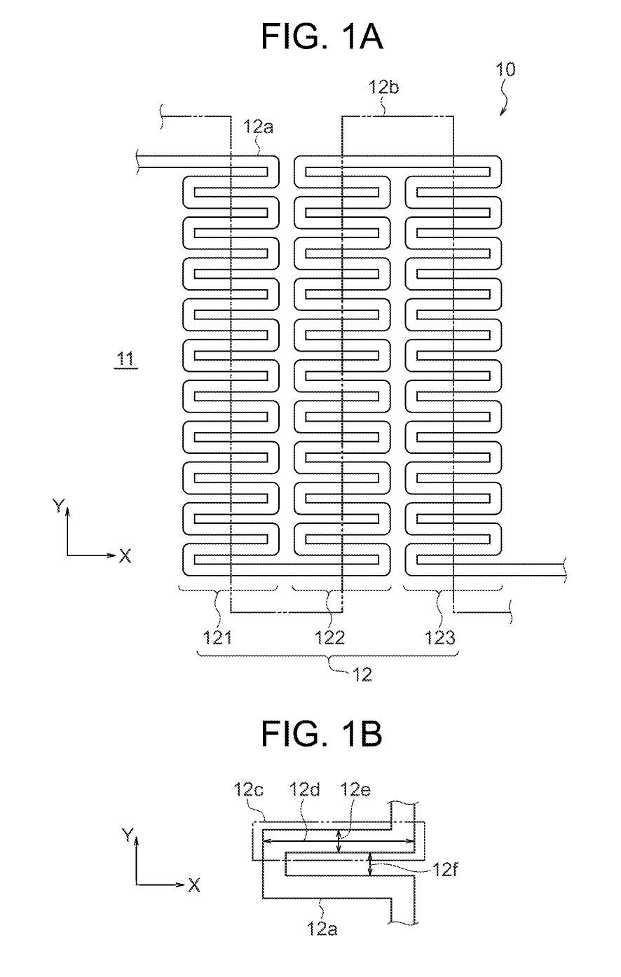

FIGS. 1A and 1B show plan views showing an MR element of a first exemplary embodiment according to the present invention, in which FIG. 1A shows the whole part thereof and FIG. 1B shows a fragmentary enlarged view. Hereinafter, explanations will be provided by referring to those drawings.

An MR element 10 of the first exemplary embodiment includes a substrate 11 and an MR film 12 provided on the substrate 11. The MR film 12 is in a shape 12b in which a straight line 12a bent in a zigzag form is further bent in a multiple zigzag form.

The straight line 12a forms a plurality of configuration parts 121, 122, and 123. Each of the configuration parts 121, 122, and 123 has a shape in which a plurality of rectangles 12c in parallel to each other are connected in series in a zigzag form, and is connected to each other in series in a zigzag form.

Each of the rectangles 12c is extended along a first direction (X direction) in a straight form, provided in parallel to each other along a second direction (Y direction) that is orthogonal to the first direction (X direction), and connected to each other in series. Each of the configuration parts 121, 122, and 123 is provided along the first direction (X direction), and connected to each other in series. In the first exemplary embodiment, as shown in the drawing, the MR element 10 includes the three configuration parts 121, 122, and 123.

Next, an example of specific dimensions will be described. A long side (length) 12d of the rectangle 12c is 65 μm, and a short side (width) 12e thereof is 9 μm. A space 12f between the rectangles 12c is 2 μm. Each of the configuration parts 121 to 123 is connected via twenty-one rectangles 12c. Further, the configuration parts 121 to 123 are in a structure in which each of those is bent back from each other three times. The thickness of the MR film 12 is 400 nm.

Next, operations and effects of the first exemplary embodiment will be described.

The resistance value of the straight-line MR film 12 becomes greater as the length thereof becomes longer, the width thereof becomes narrower, and the film thickness thereof becomes thinner. The width and the thickness of the MR film 12 are determined depending on the micromachining technology, so that there is a limit in narrowing the width and thinning the thickness. For that, with the exemplary embodiment, the MR film 12 is formed in a multiple zigzag form. Thereby, the MR film 12 can be disposed on the substrate 11 in a highly dense manner, so that the MR film 12 can be formed longer.

Therefore, since the MR element 10 includes the MR film 12 that is in the shape 12b in which the straight line 12a bent in a zigzag form is further bent in a multiple zigzag form, the resistance value of the MR element 10 can be increased. Thereby, the power consumption of the MR element 10 can be decreased.

In addition, the aspect ratio of the rectangle 12c can be made smaller with the MR element 10 compared to the case of the related technique by forming the MR film 12 in a multiple zigzag form, so that the hysteresis of the MR element 10 can be decreased. As will be described later, the hysteresis is desired to be as small as possible for the MR element 10. In the first exemplary embodiment, the aspect ratio of the rectangle 12c, i.e., long side 12d/short side 12e, is about 7. The reason for defining so is as follows.

The state where the MR element 10 is magnetized is the state where the N-pole and the S-pole appear on the surface of the rectangle 12c. Those magnetic poles generate magnetic fluxes not only outside a magnetic body but also inside the magnetic body. The magnetic field inside the magnetic body is called a diamagnetic field. The extent of the diamagnetic field is proportional to the extent of the magnetization and also depends on the shape of the magnetization direction.

The extent of the diamagnetic field when the rectangle 12c is magnetized becomes the smallest when magnetizing the rectangle 12c in the long-side direction (length direction) and becomes the largest when magnetizing it in the short-side direction (width direction). Further, when the aspect ratio of the rectangle 12c is reduced, the diamagnetic field in the short-side direction (width direction) also becomes smaller. The coercive force becomes smaller as the diamagnetic field becomes smaller, so that the hysteresis of the MR element 10 becomes smaller as well. When the pattern of the MR element 10 is actually formed, the rectangle 12c is formed as a deformed rectangle that is different from an ideal rectangle. Thus, as will be described later, the optimum value of the aspect ratio of the rectangle 12c was acquired by an experiment. As a result, it is found that the diamagnetic field becomes the smallest when the aspect ratio is about 7.

While the “multiple” is “double” in the first exemplary embodiment as shown in the drawings, the “multiple” may be “triple” or more. Further, while there are three configuration parts, there may be two configuration parts or may be four or more configuration parts. The aspect ratio may also be defined as a value other than 7.

As an exemplary advantage according to the invention, the present invention includes the MR film in a shape in which the straight line bent in a zigzag form is further bent in a multiple zigzag form, thereby making it possible to increase the resistance value of the MR element. Therefore, it is possible to decrease the power consumption of the MR element.

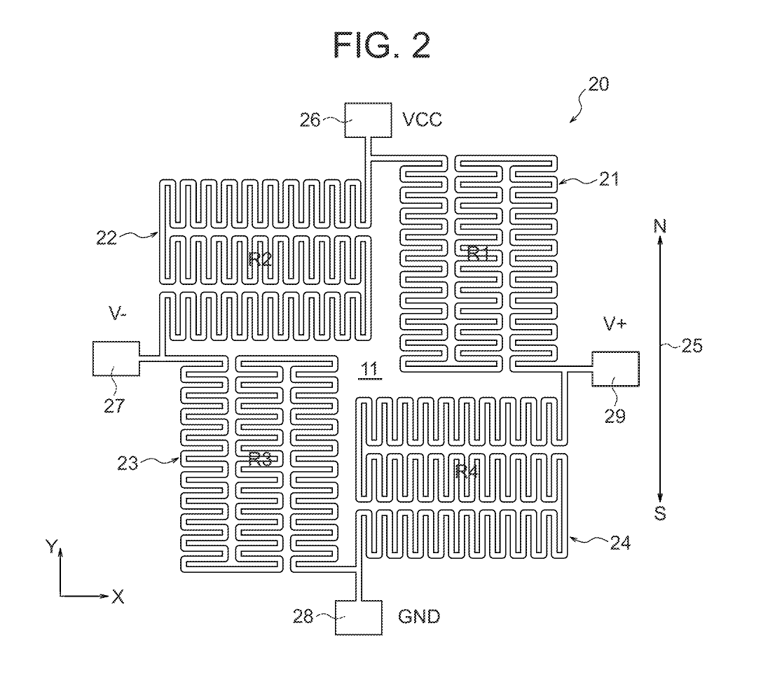

FIG. 2 is a plan view showing an MR element of a second exemplary embodiment according to the present invention. Hereinafter, explanations will be provided by referring to the drawing. An MR element 20 of the second exemplary embodiment includes four MR elements of the first exemplary embodiment, i.e., MR elements 21 to 24. As in the case of the first exemplary embodiment, the direction (long-side direction) along which the rectangles constituting the MR elements 21 to 24 are extended is defined as the first direction. In this case, the first direction (X direction) of any of the two MR elements 21, 23 out of the four MR elements 21 to 24 and the first direction (Y direction) of the remaining two MR elements 22, 24 are orthogonal to each other.

For a magnetic field applying direction 25, the resistance values of the MR elements 21, 23 are reduced, and the resistance values of the MR elements 22, 24 are almost unchanged. The MR element 20 further includes an electrode 26 for power supply voltage, an electrode 27 for −output voltage, an electrode for ground potential, and an electrode 29 for +output voltage. The MR element 21 is connected between the electrodes 29 and 26, the MR element 22 is connected between the electrodes 26 and 27, the MR element 23 is connected between the electrodes 27 and 28, and the MR element 24 is connected between the electrodes 28 and 29. These electrodes as a whole constitute a Wheatstone bridge.

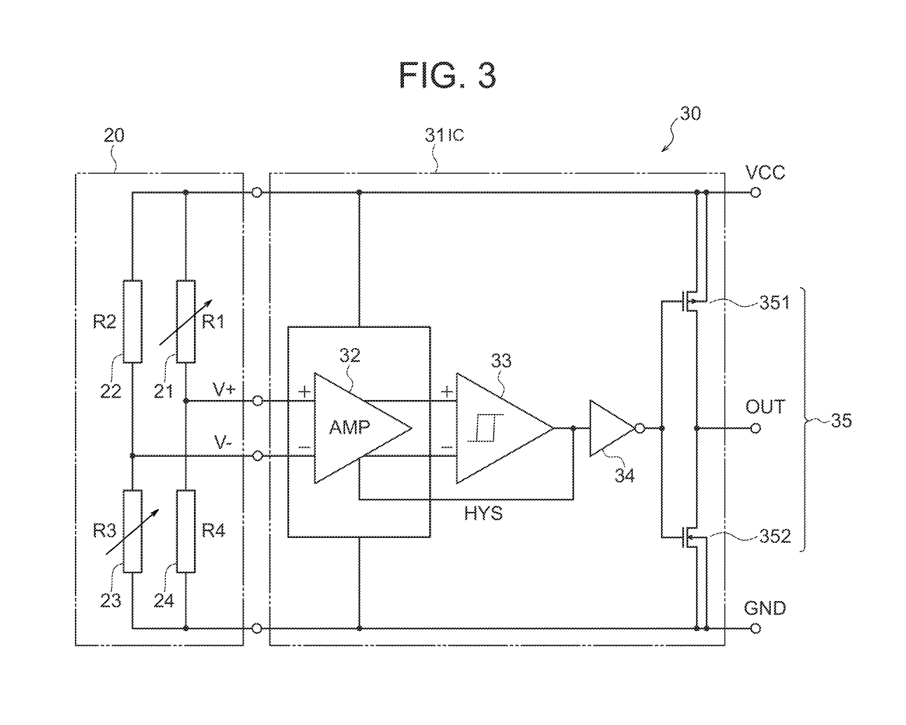

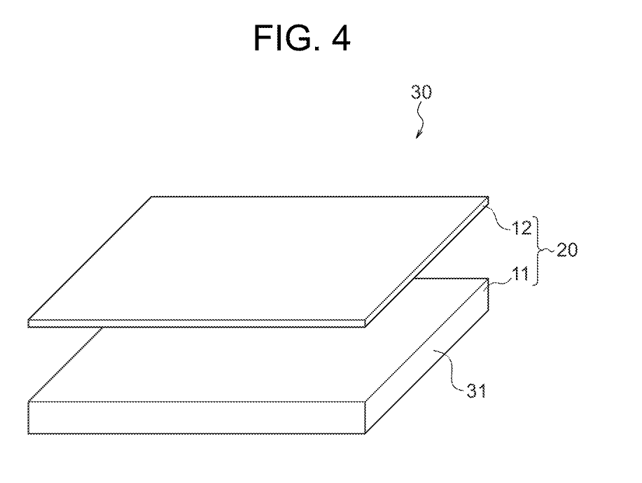

FIG. 3 is a circuit diagram showing a magnetic sensor of a third exemplary embodiment according to the present invention. FIG. 4 is a detailed perspective view showing the stereoscopic structure of the magnetic sensor shown in FIG. 3. Hereinafter, explanations will be provided by referring to FIG. 2, FIG. 3, and FIG. 4.

A magnetic sensor 30 of the third exemplary embodiment includes the MR element 20 of the second exemplary embodiment, and an integrated circuit (referred to as IC hereinafter) 31 as an electronic circuit for processing a signal of a magnetic field intensity detected by the MR element 20. The MR element 20 and the IC 31 are formed in an integrated manner.

As shown in FIG. 3, the MR element 20 is constituted with the MR elements 22, 24 as the resistors and the MR elements 21, 23 as variable resistors whose resistance values change according to the external magnetic field. The resistance values of the MR elements 22, 24 are R2, R4, and the resistance values of the MR elements 21, 23 are R1, R3. When there is the external magnetic field, the middle point potential difference ΔV=(V+)−(V−) of the bridge circuit becomes greater as the resistance values of the MR elements 21, 23 becomes smaller.

The IC 31 is constituted with an amplifier circuit 32, a comparator circuit 33, an inverter circuit 34, and an output circuit 35. The amplifier circuit 32 expands the voltage difference from the MR element 20, and outputs it as an input signal of the comparator circuit 33. The comparator circuit 33 changes the expanded voltage difference signal into two digital signals of high and low.

The positive and negative of the digital signals are inverted by the inverter circuit 34 to drive the output circuit 35. The output circuit 35 is a CMOS (Complementary Metal Oxide Semiconductor) circuit. Specifically, it is constituted with a P-channel MOSFET (MOS Field Effect Transistor) 351 on the power supply side and an N-channel MOSFET 352 on the GND side.

As shown in FIG. 4, the stereoscopic structure of the magnetic sensor 30 is a structure in which the MR film 12 and the IC 31 also functioning as the substrate 11 are stacked. The MR element 20 is constituted with the MR film 12 and the substrate 11. The MR film 12 is formed by depositing a ferromagnetic metal such as Ni or Fe in the pattern of the MR element 20 on the substrate 11 also functioning as the IC 31.

As shown in FIG. 2, the pattern of the MR element 20 is constituted with patterns of the MR elements 21 to 24 and patterns of the electrodes 26 to 29. Each of the patterns of the MR elements 21 to 24 is formed by a great number of connected rectangle patterns, and those are further bent back in a zigzag form three times. Further, in order to decrease the diamagnetic field in the width direction of the rectangle pattern, the aspect ratio is set to be about 7. In each of the MR elements 21 to 24, the same pattern is bent back three times. Thus, the area of the IC 31 (substrate 11) can be utilized in the best possible manner, so that the resistance value can be maximized. The magnetic field applying direction 25 is the case where the magnetic sensor 30 is in action, which is perpendicular to the long sides of the rectangles that constitute the MR elements 21, 23 and in parallel to the long sides of the rectangles that constitute the MR elements 22, 24. When a magnetic field is applied to the MR element 20, the resistance values of the MR elements 21, 23 are decreased while there is almost no change in the resistance values of the MR elements 22, 24. Thus, the output voltage, i.e., the potential difference between the electrode 29 (V+) and the electrode 27 (V−), is increased due to the increase in the applied magnetic field.

Hereinafter, the result of the experiment regarding the MR element of the second exemplary embodiment and the MR element of the comparative example will be described.

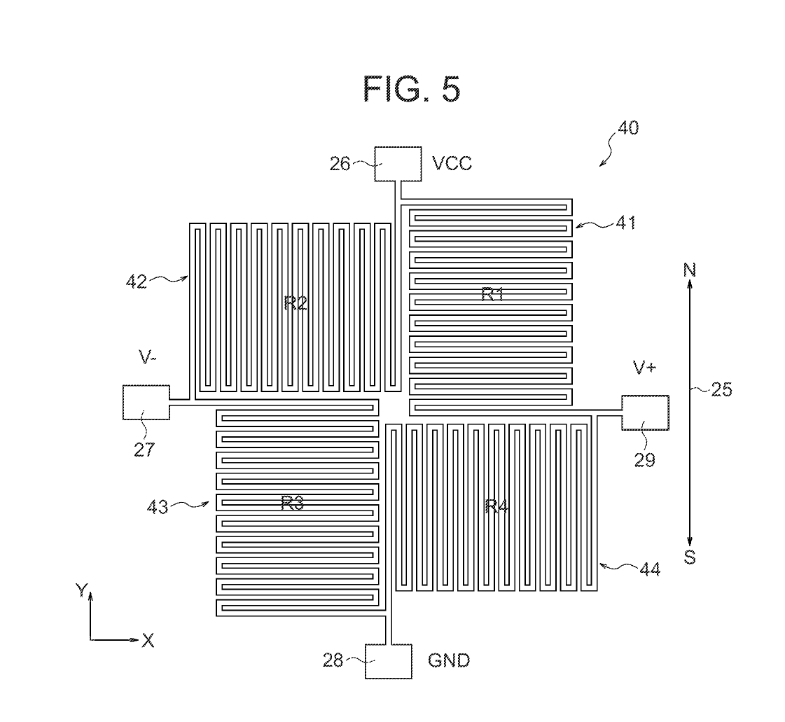

FIG. 5 is a plan view showing the MR element of the comparative example. Hereinafter, explanations will be provided by referring to the drawing. In FIG. 5, same reference numerals are applied to the same components as those of FIG. 2.

The pattern of the MR element 40 of the comparative example is constituted with patterns of MR elements 41 to 44 and patterns of the electrodes 26 to 29. Each of the patterns of the MR elements 41 to 44 is formed by a great number of connected rectangle patterns. However, unlike the case of the second exemplary embodiment, those are not in a bent-back form. The aspect ratio of the rectangle pattern is about 26.

In order to maximize the resistance value of the MR element 40, the pattern of the MR element 40 is drawn around all over the substrate (IC). The magnetic field applying direction 25 shows the case where the magnetic sensor is in action, which is perpendicular to the long sides of the rectangles that constitute the MR elements 41, 43 and in parallel to the long sides of the rectangles that constitute the MR elements 42, 44. When a magnetic field is applied to the MR element 40, the resistance values of the MR elements 41, 43 are decreased while there is almost no change in the resistance value of the MR elements 42, 44. Thus, the output voltage, i.e., the potential difference between the electrode 29 (V+) and the electrode 27 (V−), is increased due to the increase in the applied magnetic field. Other structures of the MR element 40 are the same as the case of the second exemplary embodiment.

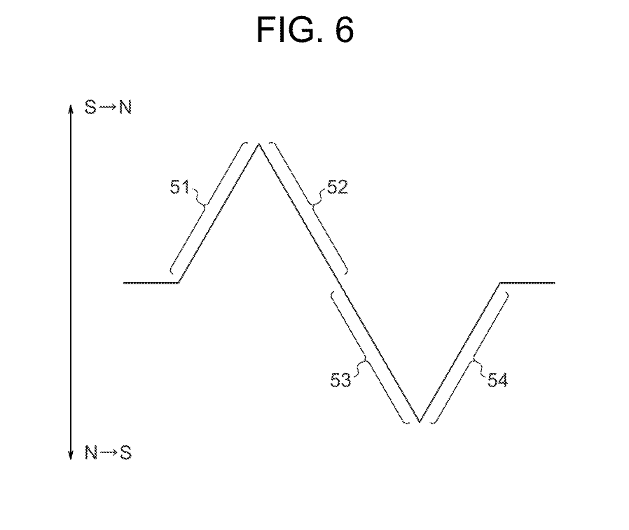

FIG. 6 is a graph 1 showing a magnetic field applied to the MR elements of the comparative example and the second exemplary embodiment. Explanations will be provided by referring to the drawing.

In FIG. 6, the lateral axis is the time and the longitudinal axis is the intensity of the applied magnetic field. Line 51 shows to increase (UP) the magnetic field intensity of the S→N direction from 0 mT to 10 mT. Line 52 shows to decrease (DOWN) the magnetic field intensity of the S→N direction from 10 mT to 0 mT. Line 53 shows to increase (UP) the magnetic field intensity of the N→S direction from 0 mT to 10 mT by changing the S→N direction to the N→S direction. Line 54 shows to decrease (DOWN) the magnetic field intensity of the N→S direction from 10 mT to 0 mT. Hereinafter, the magnetic field applying method shown in FIG. 6 is referred to as “a method without apply of ferromagnetic field”.

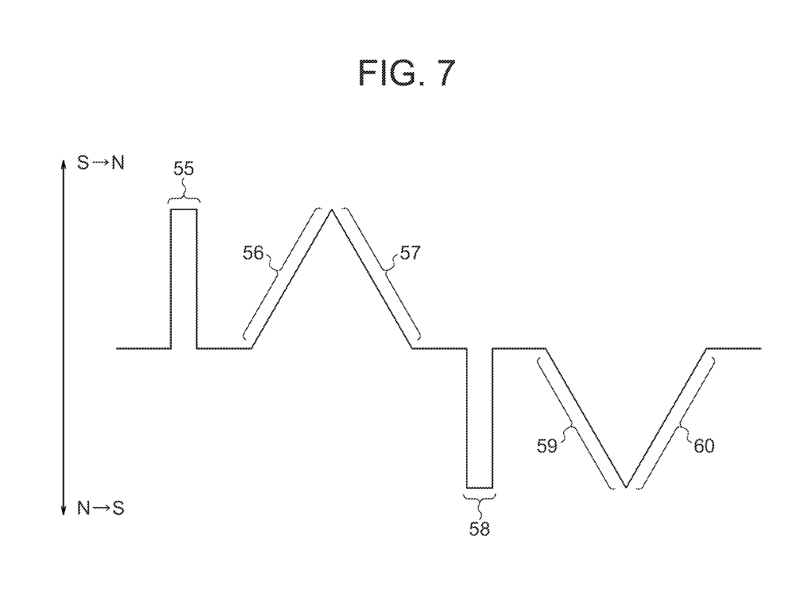

FIG. 7 is graph 2 showing a magnetic field applied to the MR elements of the comparative example and the second exemplary embodiment. Explanations will be provided by referring to the drawing.

In FIG. 7, the lateral axis is the time and the longitudinal axis is the intensity of the applied magnetic field. Line 55 shows to apply the ferromagnetic field (e.g., 10 mT) of the S→N direction. Line 56 shows to increase (UP) the magnetic field intensity of the S→N direction from 0 mT to 10 mT after applying the ferromagnetic field of the S→N direction. Line 57 shows to decrease (DOWN) the magnetic field intensity of the S→N direction from 10 mT to 0 mT. Line 58 shows to apply the ferromagnetic field (e.g., 10 mT) of the N→S direction. Line 59 shows to increase (UP) the magnetic field intensity of the N→S direction from 0 mT to 10 mT after applying the ferromagnetic field of the N→S direction. Line 60 shows to decrease (DOWN) the magnetic field intensity of the N→S direction from 10 mT to 0 mT. Hereinafter, the magnetic field applying method shown in FIG. 7 is referred to as “a method with apply of ferromagnetic field”.

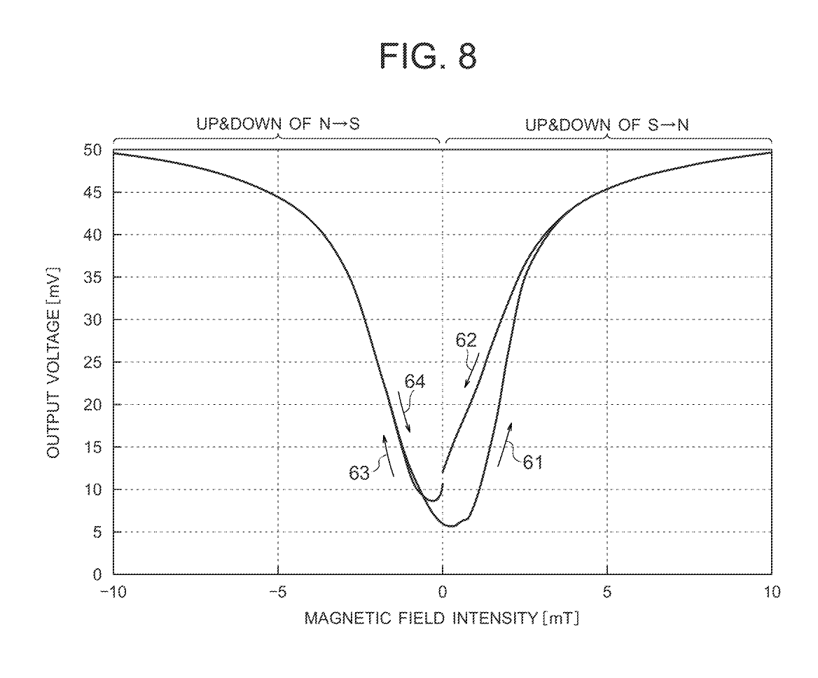

FIG. 8 is a graph (without apply of ferromagnetic field) showing the relation between the applied magnetic field and the output voltage of the MR element of the comparative example. Hereinafter, explanations will be provided by referring to FIG. 5, FIG. 6, and FIG. 8.

FIG. 8 shows the measurement values acquired by the method without apply of ferromagnetic field shown in FIG. 6. The positive direction of the lateral axis is the magnetic field intensity of the S→N direction, and the negative direction of the lateral axis is the magnetic field intensity of N→S direction. The longitudinal axis is the output voltage of the MR element 40, i.e., the middle point potential difference ΔV=(V+)−(V−) of the bridge circuit.

Curve 61 shows the change in the output voltage when the magnetic field intensity of the S→N direction is increased (UP) from 0 mT to 10 mT, and curve 62 shows the change in the output voltage when the magnetic field intensity of the S→N direction is decreased (DOWN) from 10 mT to 0 mT. When the magnetic field intensity is 0 mT, the difference in the output voltages (offset voltages) of the cases of “UP” and “DOWN” is about 7 mV.

Curve 63 shows the change in the output voltage when the magnetic field intensity of the N→S direction is increased (UP) from 0 mT to 10 mT, and curve 64 shows the change in the output voltage when the magnetic field intensity of the N→S direction is decreased (DOWN) from 10 mT to 0 mT. When the magnetic field intensity is 0 mT, the difference in the output voltages (offset voltages) of the cases of “UP” and “DOWN” is about 7 mV.

As described, with the MR element of the comparative example, there is the hysteresis of the magnetic sensor (magnetic field intensity difference between “ON” and “OFF” of the magnetic sensor) due to “UP” and “DOWN” in both of the S→N direction and the N→S direction.

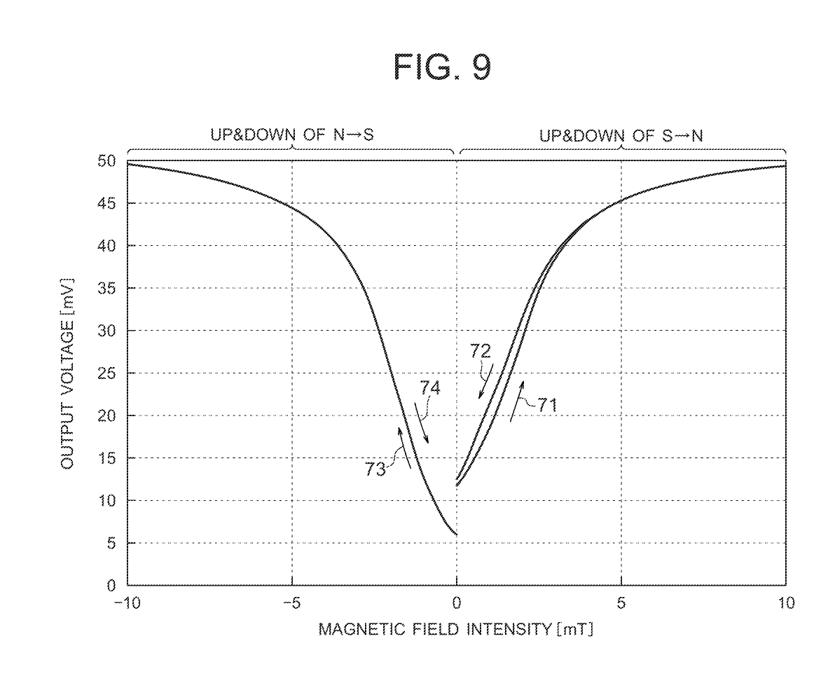

FIG. 9 is a graph (with apply of ferromagnetic field) showing the relation between the applied magnetic field and the output voltage of the MR element of the comparative example. Hereinafter, explanations will be provided by referring to FIG. 5, FIG. 7, and FIG. 9.

FIG. 9 shows the measurement values acquired by the method with apply of ferromagnetic field shown in FIG. 7. The positive direction of the lateral axis is the magnetic field intensity of the S→N direction, and the negative direction of the lateral axis is the magnetic field intensity of the N→S direction. The longitudinal axis is the output voltage of the MR element 40, i.e., the middle point potential difference ΔV=(V+)−(V−) of the bridge circuit.

Curve 71 shows the change in the output voltage when the magnetic field intensity of the S→N direction is increased (UP) from 0 mT to 10 mT after applying the ferromagnetic field (e.g., 10 mT) of the S→N direction. Curve 72 shows the change in the output voltage when the magnetic field intensity of the S→N direction is decreased (DOWN) from 10 mT to 0 mT. When the magnetic field intensity is 0 mT, the output voltages (offset voltages) of the cases of “UP” and “DOWN” are almost the same.

Curve 73 shows the change in the output voltage when the magnetic field intensity of the N→S direction is increased (UP) from 0 mT to 10 mT after applying the ferromagnetic field (e.g., 10 mT) of the N→S direction. Curve 74 shows the change in the output voltage when the magnetic field intensity of the N→S direction is decreased (DOWN) from 10 mT to 0 mT. When the magnetic field intensity is 0 mT, the output voltages (offset voltages) of the cases of “UP” and “DOWN” are almost the same.

As described, with the MR element of the comparative example, there is almost no hysteresis of the magnetic sensor (magnetic field intensity difference between “ON” and “OFF” of the magnetic sensor) by “UP” and “DOWN” in both of the S→N direction and the N→S direction. However, between the S→N direction and the N→S direction, there is about 7 mV difference in the output voltages (offset voltages) when the magnetic field intensity is 0 mT. In other words, there is a difference in the sensitivity of the magnetic sensor depending on the magnetic field applying directions.

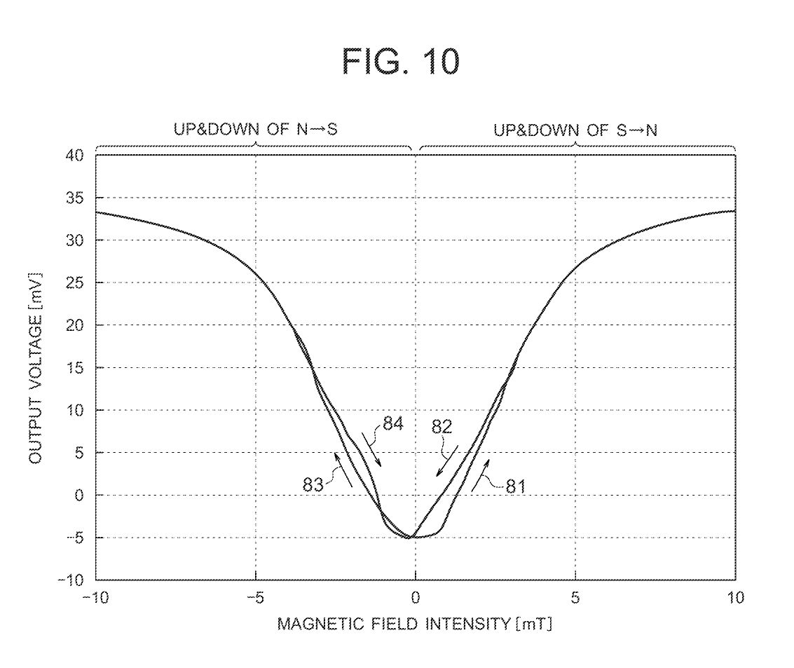

FIG. 10 is a graph (without apply of ferromagnetic field) showing the relation between the applied magnetic field and the output voltage of the MR element of the second exemplary embodiment. Hereinafter, explanations will be provided by referring to FIG. 2, FIG. 6, and FIG. 10.

FIG. 10 shows the measurement values acquired by the method without apply of ferromagnetic field shown in FIG. 6. The positive direction of the lateral axis is the magnetic field intensity of the S→N direction, and the negative direction of the lateral axis is the magnetic field intensity of the N→S direction. The longitudinal axis is the output voltage of the MR element 20, i.e., the middle point potential difference ΔV=(V+)−(V−) of the bridge circuit.

Curve 81 shows the change in the output voltage when the magnetic field intensity of the S→N direction is increased (UP) from 0 mT to 10 mT. Curve 82 shows the change in the output voltage when the magnetic field intensity of the S→N direction is decreased (DOWN) from 10 mT to 0 mT. When the magnetic field intensity is 0 mT, the output voltages (offset voltages) of the cases of “UP” and “DOWN” are almost the same.

Curve 83 shows the change in the output voltage when the magnetic field intensity of the N→S direction is increased (UP) from 0 mT to 10 mT. Curve 84 shows the change in the output voltage when the magnetic field intensity of the N→S direction is decreased (DOWN) from 10 mT to 0 mT. When the magnetic field intensity is 0 mT, the output voltages (offset voltages) of the cases of “UP” and “DOWN” are almost the same.

As described, with the MR element of the second exemplary embodiment, there is almost no hysteresis of the magnetic sensor (magnetic field intensity difference between “ON” and “OFF” of the magnetic sensor) by “UP” and “DOWN” in both of the S→N direction and the N→S direction. The reason is as follows. That is, the MR film of the MR element according to the second embodiment is formed in a multiple zigzag form, so that the aspect ratio of the rectangle becomes smaller than the case of the comparative example. Therefore, the hysteresis of the MR element can be made smaller.

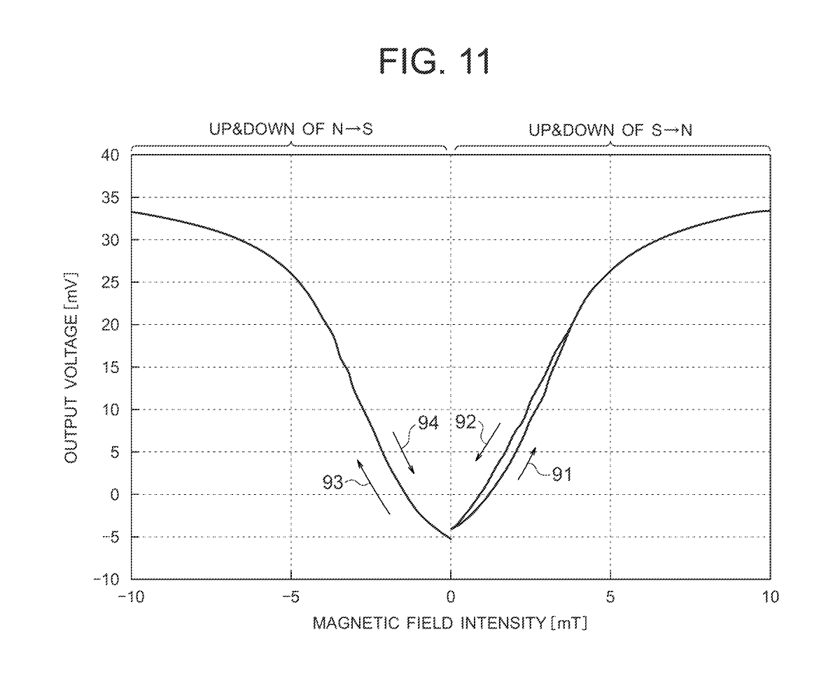

FIG. 11 is a graph (with apply of ferromagnetic field) showing the relation between the applied magnetic field and the output voltage of the MR element of the second exemplary embodiment. Hereinafter, explanations will be provided by referring to FIG. 2, FIG. 7, and FIG. 11.

FIG. 11 shows the measurement values acquired by the method with apply of ferromagnetic field shown in FIG. 7. The positive direction of the lateral axis is the magnetic field intensity of the S→N direction, and the negative direction of the lateral axis is the magnetic field intensity of the N→S direction. The longitudinal axis is the output voltage of the MR element 20, i.e., the middle point potential difference ΔV=(V+)−(V−) of the bridge circuit.

Curve 91 shows the change in the output voltage when the magnetic field intensity of the S→N direction is increased (UP) from 0 mT to 10 mT after applying the ferromagnetic field (e.g., 10 mT) of the S→N direction. Curve 92 shows the change in the output voltage when the magnetic field intensity of the S→N direction is decreased (DOWN) from 10 mT to 0 mT. When the magnetic field intensity is 0 mT, the output voltages (offset voltages) of the cases of “UP” and “DOWN” are almost the same.

Curve 93 shows the change in the output voltage when the magnetic field intensity of the N→S direction is increased (UP) from 0 mT to 10 mT after applying the ferromagnetic field (e.g., 10 mT) of the N→S direction. Curve 94 shows the change in the output voltage when the magnetic field intensity of the N→S direction is decreased (DOWN) from 10 mT to 0 mT. When the magnetic field intensity is 0 mT, the output voltages (offset voltages) of the cases of “UP” and “DOWN” are almost the same.

As described, with the MR element of the second exemplary embodiment, there is almost no hysteresis of the magnetic sensor (magnetic field intensity difference between “ON” and “OFF” of the magnetic sensor) by “UP” and “DOWN” in both of the S→N direction and the N→S direction. Further, the output voltages (offset voltages) when the magnetic field intensity is 0 mT are almost the same in the S→N direction and the N→S direction. In other words, there is almost no difference in the sensitivity of the magnetic sensor depending on the magnetic field applying directions. The reason is as follows. That is, the MR film of the MR element according to the second embodiment is formed in a multiple zigzag form, so that the aspect ratio of the rectangle becomes smaller than the case of the comparative example. Therefore, the hysteresis of the MR element can be made smaller.

Next, the present invention will be summarized.

The present invention relates to the magnetic sensor which maximizes the resistance value of the MR element and minimizes the consumption of the electric current by bending back the pattern of the MR element three times. Further, the present invention relates to the magnetic sensor which minimizes the hysteresis (difference in the magnetic field intensities of “ON” and “OFF” of the magnetic sensor) in “UP” and “DOWN” of the applied magnetic field and the difference in the magnetic field sensitivities between the N→S direction and the S→N direction by optimizing the aspect ratio (the ratio between the element length and the element width) of the pattern of the MR element in accordance with the property of the MR element. Furthermore, the present invention relates to the magnetic sensor which is provided with the MR element, the amplifier circuit, the comparator circuit, and the C-MOS output circuit to output a HIGH level when the external magnetic field intensity exceeds the sensitivity threshold value and to output a LOW level when the external magnetic field intensity is smaller than the sensitivity threshold value. Moreover, the present invention relates to the magnetic sensor in which the MR element and the IC are integrated.

The effects of the present invention are as follows. The entire power consumption of the magnetic sensor is decreased by providing a new MR element pattern. There is almost no offset voltage difference in the MR element generated by “UP” and “DOWN” of the applied magnetic field. There is almost no hysteresis of the magnetic sensor (the magnetic field intensity difference in “ON” and “OFF” of the magnetic sensor), either. There is almost no offset voltage difference in the MR element generated depending on the magnetic field applying directions of the S→N direction and the N→S direction after applying the ferromagnetic field. There is almost no sensitivity difference of the magnetic sensor generated depending on the magnetic field applying directions after applying the ferromagnetic field. It is possible to minimize the size of the magnetic sensor and to suppress variations in the property depending on the MR element by integrating the MR element and the IC.

While the present invention has been described heretofore by referring to each of the exemplary embodiments, the present invention is not limited only to each of the exemplary embodiments described above. Various changes and modifications occurred to those skilled in the art can be applied to the structures and details of the present invention. Further, it is to be noted that the present invention also includes the structures acquired by properly combining a part of or whole parts of each of the above-described exemplary embodiments mutually.

While a part of or a whole part of the exemplary embodiment disclosed heretofore can be properly expressed by following Supplementary Notes, the present invention is not limited only to the following structures.

### (Supplementary Note 1)

A magnetoresistance element which includes a substrate and a magnetoresistance film provided on the substrate, wherein the magnetoresistance film is in a shape in which a straight line bent in a zigzag form is further bent in a multiple zigzag form.

### (Supplementary Note 2)

The magnetoresistance element as depicted in Supplementary Note 1, wherein: the “multiple” zigzag form is a “double” zigzag form; the straight line forms a plurality of configuration parts; and each of the configuration parts is in a form in which a plurality of rectangles in parallel to each other are connected in series in a zigzag form, and the configuration parts are connected to each other in series in a zigzag form.

### (Supplementary Note 3)

The magnetoresistance element as depicted in Supplementary Note 2, wherein: each of the rectangles is extended along a first direction in a straight manner, provided in parallel to each other along a second direction that is orthogonal to the first direction, and connected to each other in series; and each of the configured parts is provided along the first direction and connected to each other in series.

### (Supplementary Note 4)

The magnetoresistance element as depicted in Supplementary Note 2 or 3, which includes three pieces of the configuration parts.

### (Supplementary Note 5)

The magnetoresistance element as depicted in any one of Supplementary Notes 2 to 4, wherein an aspect ratio of the rectangle is about 7.

### (Supplementary Note 6)

A magnetoresistance element which includes four pieces of the magnetoresistance elements depicted in any one of Supplementary Notes 3 to 5, wherein: the first direction of any of the two magnetoresistance elements out of the four magnetoresistance elements is orthogonal to the first direction of the remaining two magnetoresistance elements.

### (Supplementary Note 7)

A magnetic sensor which includes: the magnetoresistance element depicted in Supplementary Notes 1 to 6; and an electronic circuit which processes a signal of a magnetic field intensity detected by the magnetoresistance element.

### (Supplementary Note 8)

The magnetic sensor as depicted in Supplementary Note 7, wherein: the electronic circuit is an integrated circuit; and the integrated circuit and the magnetoresistance element are integrated.

### (Supplementary Note 11)

A magnetic sensor which minimizes the consumed electric current by maximizing the resistance value of an MR element through bending back an MR element pattern three times.

### (Supplementary Note 12)

A magnetic sensor which minimizes a hysteresis of the magnetic sensor (a magnetic field intensity different in “ON” and “OFF” of the magnetic sensor) by “UP” and “DOWN” of an applied magnetic field and minimizes a magnetic field sensitivity difference between the S→N direction and the N→S direction by optimizing the aspect ratio (ratio of the element length and the element width) of the MR element pattern for the property of the MR element.

### (Supplementary Note 13)

A magnetic sensor including the MR element depicted in Supplementary Note 11 or 12, the MR element, an amplifier circuit, a comparator circuit, and a C-MOS output circuit, which outputs a HIGH level when an external magnetic field intensity exceeds a sensitivity threshold value and outputs a LOW level when the external magnetic field intensity is smaller than the sensitivity threshold value.

### (Supplementary Note 14)

The magnetic sensor as depicted in Supplementary Note 13, wherein the MR element and an IC are integrated.

The present invention can be utilized for a rotating detection unit of a water meter and a gas meter, an encoder of a motor, and the like, for example.

What is claimed is:

1. A magnetoresistance element, comprising a substrate and a magnetoresistance film provided on the substrate, wherein
the magnetoresistance film is in a shape in which a straight line bent in a zigzag form is further bent in a multiple zigzag form.

2. The magnetoresistance element as claimed in claim 1, wherein:
the “multiple” zigzag form is a “double” zigzag form;
the straight line forms a plurality of configuration parts; and
each of the configuration parts is in a form in which a plurality of rectangles in parallel to each other are connected in series in a zigzag form, and the configuration parts are connected to each other in series in a zigzag form.

3. The magnetoresistance element as claimed in claim 2, wherein:
each of the rectangles is extended along a first direction in a straight manner, provided in parallel to each other along a second direction that is orthogonal to the first direction, and connected to each other in series; and
each of the configured parts is provided along the first direction and connected to each other in series.

4. The magnetoresistance element as claimed in claim 2, comprising three pieces of the configuration parts.

5. The magnetoresistance element as claimed in claim 2, wherein
an aspect ratio of the rectangle is about 7.

6. A magnetoresistance element, comprising four pieces of the magnetoresistance elements claimed in claim 3, wherein:
the first direction of any of the two magnetoresistance elements out of the four magnetoresistance elements is orthogonal to the first direction of the remaining two magnetoresistance elements.

7. A magnetic sensor, comprising:
the magnetoresistance element claimed in claim 1; and
an electronic circuit which processes a signal of a magnetic field intensity detected by the magnetoresistance element.

8. The magnetic sensor as claimed in claim 7, wherein:
the electronic circuit is an integrated circuit; and
the integrated circuit and the magnetoresistance element are integrated.
